(19) United States
(12) Patent Application Publication
(10) Pub. No.: US 2025/0253894 A1
(43) Pub. Date: Aug. 7, 2025

(54) RECONFIGURABLE INTELLIGENT SURFACE AND CONTROL APPARATUS AND METHOD THEREFOR

(71) Applicant: UIF (University Industry Foundation), Yonsei University, Seoul (KR)

(72) Inventors: Byung-Wook MIN, Seoul (KR); Sungeun KIM, Seoul (KR); Dohoon CHUN, Seoul (KR); Jaekwan LEE, Seoul (KR)

(21) Appl. No.: 18/967,447

(22) Filed: Dec. 3, 2024

(30) Foreign Application Priority Data
Feb. 5, 2024 (KR) 10-2024-0017142

(51) Int. Cl. H04B 7/04; H03K 19/0175; H04L 27/18

(52) U.S. Cl. CPC H04B 7/04013; H03K 19/017509; H04L 27/18

(57) ABSTRACT

Provided are a Reconfigurable Intelligent Surface (RIS) unit, and a control apparatus and method thereof. The control apparatus includes a voltage determination module that is activated when a first power supply voltage is applied, receives serial data, and obtains a plurality of level determination signals, a voltage fixing module that is driven when a second power supply voltage is applied, and stores a plurality of phase control signals obtained by level-shifting each of the plurality of level determination signals transmitted from the voltage determination module, and a phase shifting module configured to adjust a phase of a signal received by each of a plurality of radiators according to the plurality of phase control signals.

### CROSS-REFERENCE TO RELATED APPLICATION

This application claims priority under 35 U.S.C. § 119(a) to and the benefit of Korean Patent Application No. 2024-0017142, filed on Feb. 5, 2024 in the Korean Intellectual Property Office, the disclosure of which is incorporated herein by reference in its entirety.

### BACKGROUND

### 1. Field of the Invention

The present disclosure relates to a Reconfigurable Intelligent Surface (RIS) and a control apparatus and method thereof.

### 2. Discussion of Related Art

FIG. 1 illustrates an example of a Reconfigurable Intelligent Surface (RIS).

Referring to FIG. 1, an RIS may be utilized to enable communication in non-line-of-sight (NLOS) situations, such as when obstacles exist between a base station (BS) and user equipment (UE) of wireless communication, or to increase the efficiency of communication between the BS and the UE. Unlike a simple reflective surface, an RIS may not only determine whether an incident signal is reflected, but also control the phase of the signal to adjust the reflection angle or intensity of the signal. Further, the RIS may operate differently depending on polarization.

As illustrated in FIG. 1, such an RIS includes a set of a plurality of RIS units, and each of the plurality of RIS units may include a radiator that reflects (receives and then transmits) a wireless communication signal, a phase shifter that adjusts a phase of the received signal, a bias controller that controls the phase shifter, etc.

Conventionally, each of RIS units has been implemented by first manufacturing a radiator and a phase shifter integrally, then separately manufacturing a bias controller for controlling the phase shifter, and combining the same. However, such an implementation method has the limitations of low versatility because the bias controller should be individually manufactured to match the pre-manufactured phase shifter and low flexibility, as a circuit needs to be redesigned every time even when it is desired to manufacture the RIS in a size appropriate for the situation.

### SUMMARY

The present disclosure is directed to providing a Reconfigurable Intelligent Surface (RIS) that is capable of controlling phases of signals applied to a plurality of radiators with a single control module to have high versatility and expandability, and a control apparatus and method thereof.

The present disclosure is also directed to providing an RIS capable of reducing power consumption, and a control apparatus and method thereof.

According to an aspect of the present disclosure, there is provided a control apparatus for an RIS, which includes a voltage determination module that is activated when a first power supply voltage is applied, receives serial data, and obtains a plurality of level determination signals, a voltage fixing module that is driven when a second power supply voltage having a higher voltage level than the first power supply voltage is applied, and stores a plurality of phase control signals obtained by level-shifting each of the plurality of level determination signals transmitted from the voltage determination module, and a phase shifting module configured to adjust a phase of a signal received by each of a plurality of radiators according to the plurality of phase control signals.

The first power supply voltage may be applied before the serial data is transmitted, and may be blocked after the plurality of phase control signals are stored in the voltage fixing module.

The voltage determination module may include a data interpretation module that extracts the plurality of level determination signals from the serial data in synchronization with a clock signal applied together with the serial data, and a buffer module that converts each of the plurality of level determination signals into a differential signal and outputs a plurality of differential level determination signals.

The buffer module may include a buffer that receives the level determination signals, buffers the level determination signals, and outputs the level determination signals, and an inverter that receives the level determination signals, inverts the level determination signals, and outputs the inverted level determination signals.

The voltage determination module may further include a diode connected in series between the first power supply voltage and the buffer module, and a capacitor connected in parallel between the diode and the buffer module.

The control apparatus may further include a switch circuit that is positioned between the voltage determination module and the voltage fixing module and electrically connects the voltage determination module and the voltage fixing module when the first power supply voltage is applied.

The voltage fixing module may include a plurality of latches that are driven when the second power supply voltage is applied, and receive and store each of the plurality of level determination signals.

The phase shifting module may include a plurality of phase shifters that are implemented as transistors, wherein the transistors are connected between one of the plurality of radiators and a ground voltage and connect or disconnect the radiator and the ground voltage according to a level of a corresponding one of the plurality of phase control signals.

According to another aspect of the present disclosure, there is provided a control method for an RIS, which is a method performed by a control module included in the RIS unit in which a plurality of radiators are arranged, wherein the control method includes when a first power supply voltage is applied, receiving serial data and obtaining a plurality of level determination signals, storing a plurality of phase control signals obtained by level-shifting each of the plurality of level determination signals into a second power supply voltage having a higher voltage level than the first power supply voltage, and adjusting a phase of a signal received by each of the plurality of radiators according to the plurality of phase control signals.

According to still another aspect of the present disclosure, there is provided an RIS which includes a plurality of radiators, and a plurality of RIS units that each include a control module that receives serial data and obtains a plurality of level determination signals when a first power supply voltage is applied, stores a plurality of phase control signals obtained by level-shifting the plurality of level determination signals into a second power supply voltage having a higher voltage level than the first power supply voltage, and adjusts a phase of a signal received by each of the plurality of radiators according to the plurality of phase control signals.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 illustrates an example of a Reconfigurable Intelligent Surface (RIS);

FIG. 2 illustrates a schematic structure of an RIS and a control apparatus according to an embodiment of present disclosure;

FIG. 3 illustrates examples of a connection structure of the control apparatus of FIG. 2 and radiators;

FIG. 4 illustrates a schematic structure of the control apparatus of FIG. 2;

FIG. 5 illustrates an example of a detailed configuration of the control apparatus of FIG. 4;

FIG. 6 is a set of diagrams for describing operations of the control apparatus of FIG. 4; and

FIG. 7 illustrates a control method for an RIS according to an embodiment present disclosure.

### DETAILED DESCRIPTION OF EXEMPLARY EMBODIMENTS

Hereinafter, detailed embodiments of the present disclosure will be described with reference to the accompanying drawings. The following detailed description is provided to help comprehensive understanding of methods, apparatuses, and/or systems described in this specification. However, these embodiments are only examples and the present disclosure is not limited thereto.

When embodiments of the present disclosure are described, in a case in which it is determined that detailed descriptions of known technology related to the present disclosure unnecessarily obscure the subject matter of the disclosure, detailed descriptions thereof will be omitted. Some terms described below are defined by considering functions in the present disclosure and meanings may vary depending on, for example, a user or operator's intentions or customs. Therefore, the meanings of terms should be interpreted based on the scope throughout this specification. The terminology used in the following detailed description is only provided to describe embodiments of the present disclosure and not for purposes of limitation. Unless the context clearly indicates otherwise, the singular forms include the plural forms. It will be understood that the terms “comprise” and “include” used herein specify some features, numbers, steps, operations, elements, and parts or combinations thereof, but do not preclude the presence or possibility of one or more other features, numbers, steps, operations, elements, and parts or combinations thereof in addition to those described. Moreover, terms described in the specification such as “part,” “unit,” “device,” “module,” and “block” refer to a unit of processing at least one function or operation and may be implemented as hardware or software or a combination thereof.

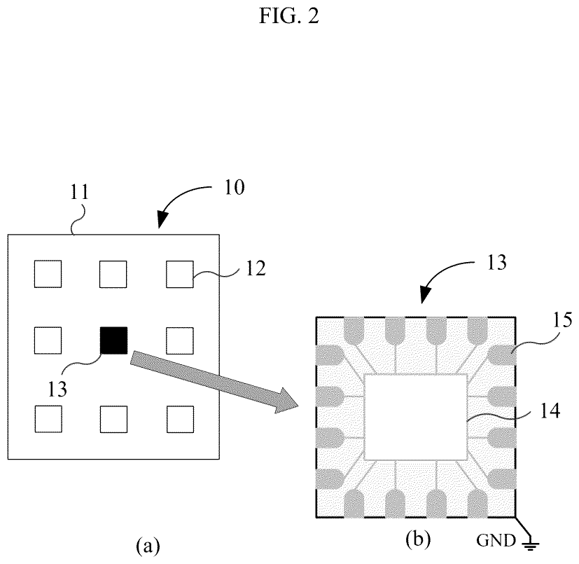

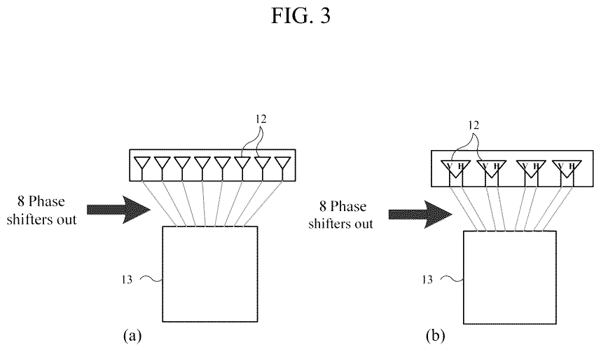

FIG. 2 illustrates a schematic structure of a Reconfigurable Intelligent Surface (RIS) unit and a control apparatus according to one embodiment, and FIG. 3 illustrates examples of a connection structure of the control apparatus of FIG. 2 and radiators.

Referring to (a) of FIG. 2, an RIS unit 10 according to one embodiment includes a substrate 11, a plurality of radiators 12, and a control apparatus 13. The number (N) of radiators 12 included in the RIS unit 10 may vary, but here, as an example, it will be described assuming that the RIS unit 10 includes eight radiators 12 arranged on the substrate 11, as illustrated in (a) of FIG. 2.

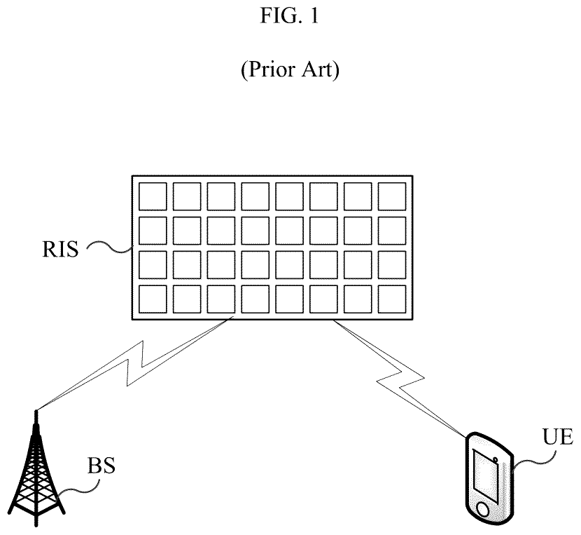

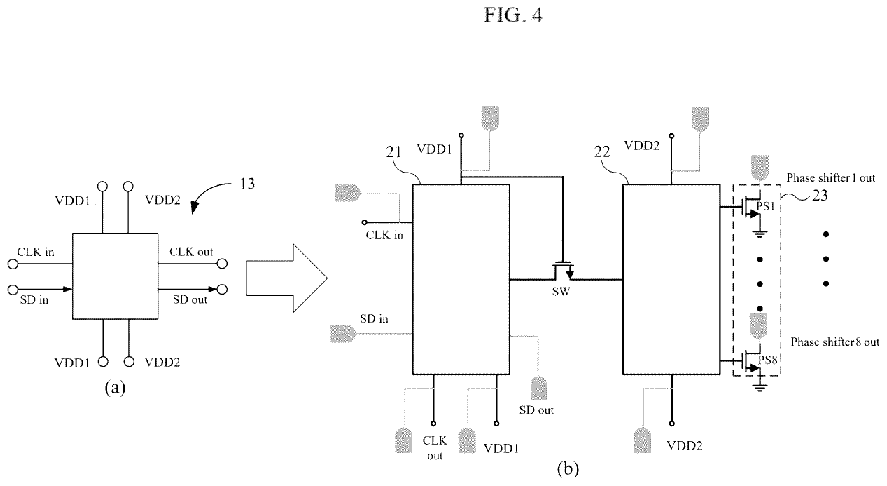

The control apparatus 13 adjusts a phase of a signal received by each of the plurality of radiators 12 provided in the RIS unit 10. Unlike FIG. 1 in which each RIS unit 10 includes only one radiator 12, the RIS unit 10 of one embodiment includes a plurality of radiators 12, and thus one control apparatus 13 is configured to adjust phases of signals of the plurality of radiators 12, and should be able to individually adjust the phase of the signal received by each of the plurality of radiators 12. Accordingly, the control apparatus 13 includes a plurality of phase shifters PS1 to PS8 illustrated in FIG. 4 corresponding to the plurality of radiators 12, and a control circuit for controlling the plurality of phase shifters PS1 to PS8.

As described above, in the conventional RIS unit, a radiator and a phase shifter are integrally manufactured and a bias controller is separately manufactured. In contrast, in the RIS unit 10 of one embodiment, the plurality of radiators 12 are separately configured and arranged on the substrate 11, and the plurality of phase shifters and the control circuit for controlling the plurality of phase shifters are included in the control apparatus 13 and are integrally configured. Therefore, the control circuit does not need to be adjusted to be appropriate for a phase controller.

In addition, in one embodiment, the control apparatus 13 may be implemented in the form of a packaged chip 14, and for example, may be implemented as a chip 14 packaged as quad flat no-leads (QFN) or the like, as illustrated in (b) of FIG. 2. When the control apparatus 13 is implemented as the packaged chip 14, the control apparatus 13 may include a plurality of pads 15 for electrical contact with lines formed on the substrate 11. Here, the plurality of pads 15 may be divided into first pads for being electrically connected to each of the plurality of radiators 12 arranged on the substrate 11, and second pads for control. When the control apparatus 13 implemented as a QFN package chip is disposed at a specified location on the substrate 11, each of the plurality of pads 15 is brought into contact with a line (not illustrated) formed on the substrate 11, the first pad among the plurality of pads 15 may be electrically connected to a corresponding radiator 12 among the plurality of radiators 12 through the line in contact therewith, and the second pad may be electrically connected to a control apparatus 13 of another RIS unit that is located adjacent thereto or a device that is located outside the substrate 11 and transmits power or a signal for control, through the line in contact therewith.

The control apparatus 13 illustrated in (b) of FIG. 2 is illustrated as including 16 pads 15, of which 8 pads are first pads and the remaining 8 pads are second pads. In addition, each of the eight first pads may be connected to a corresponding radiator 12, and in this case, each first pad may be connected to the radiator 12 in a 1:1 correspondence as illustrated in (a) of FIG. 3, whereas two first pads may be electrically connected to one radiator 12 in a 1:2 correspondence as illustrated in (b) of FIG. 3.

When the radiator 12 of the RIS unit 10 adjusts only the phase of a single polarization, each of the plurality of radiators 12 may be connected to one first pad, as illustrated in (a) of FIG. 3, but when the radiator 12 adjusts the phase of a dual polarization, each of the plurality of radiators 12 may be connected to two first pads, as illustrated in (b) of FIG. 3. In addition, here, as an example, it is assumed that the control apparatus 13 further includes eight pads as second pads for control, and the eight second pads may include four pads for input or output of first and second power supply voltages VDD1 and VDD2 to be described below and four pads for input or output of clock signals and serial data. The number of first pads connected to the radiators 12 in the control apparatus 13 may be adjusted according to the number of radiators 12 included in the RIS unit 10. However, the number of second pads for control may be maintained regardless of the number of radiators 12.

In addition, the control apparatus 13 implemented as the packaged chip 14 may be disposed on the same surface as a surface of the substrate 11 on which the plurality of radiators 12 are arranged, or in some cases, may be disposed on a surface opposite to the surface on which the plurality of radiators 12 are arranged.

FIG. 4 illustrates a schematic structure of the control apparatus of FIG. 2.

In FIG. 4, (a) of FIG. 4 illustrates the control apparatus 13 implemented as a chip 14 as illustrated in (b) of FIG. 2, and (b) FIG. 4 illustrates a schematic circuit configuration of the control apparatus 13. In (a) FIG. 4, for convenience of description, the connection lines with the first pads corresponding to the radiators 12 in the control apparatus 13 implemented as the chip 14 are omitted, and only the connection lines with the second pads that input or output the control signal is illustrated.

As described above, the control apparatus 13 includes four second pads for input or output of first and second power supply voltages VDD1 and VDD2 and four second pads for input or output of clock signals and serial data. Accordingly, as illustrated in (a) FIG. 4, the chip 14 may be formed with two lines through which the first power supply voltage VDD1 is input or output, two lines through which the second power supply voltage VDD2 is input or output, two lines CLKin and CLKout through which the clock signals are input or output, and two lines SDin and SDout through which the serial data is input or output, which are connected to eight second pads.

In addition, referring to (b) of FIG. 4, the control apparatus 13 may include a voltage determination module 21, a voltage fixing module 22, a phase shifting module 23, and a switch circuit SW.

The phase shifting module 23 may include the plurality of phase shifters PS1 to PS8 connected to the first pads, respectively. Here, since it is assumed that the control apparatus 13 includes eight first pads, the phase shifting module 23 may include eight phase shifters PS1 to PS8. In addition, each of the plurality of phase shifters PS1 to PS8 may be implemented as a transistor that is turned on or off in response to a phase control signal applied from the voltage fixing module 22, and as an example, in (b) of FIG. 4, a case in which the phase shifters PS1 to PS8 are implemented as N-type metal-oxide-semiconductor (NMOS) transistors that are connected between the second pads and a ground voltage GND and the phase control signal output from the voltage fixing module 22 is applied to a gate is illustrated.

Each of the plurality of phase shifters PS1 to PS8 may connect or disconnect the radiator 12 and the ground voltage GND that are connected through the second pad in response to the phase control signal applied at a high or low level, and thus the phase of the signal applied to the RIS including the plurality of radiators 12 may be adjusted.

The voltage determination module 21 is driven when the first power supply voltage VDD1 is applied, and receives a clock signal CLK and serial data SD. In addition, the voltage determination module 21 extracts data about itself from the serial data SD in synchronization with the clock signal CLK, determines a voltage level to be applied to the plurality of phase shifters PS1 to PS8 according to the extracted data, and transmits a plurality of level determination signals corresponding to the determined voltage level to the voltage fixing module 22. In addition, the voltage determination module 21 outputs the applied first power supply voltage VDD1, the clock signal CLK, and the serial data SD to be transmitted to the control apparatus 13 of the RIS unit, which is disposed adjacent thereto through the second pads.

Meanwhile, the voltage fixing module 22 is driven when the second power supply voltage VDD2 is applied, and receives the plurality of level determination signals applied from the voltage determination module 21. In addition, the voltage fixing module 22 latches and stores each of the plurality of applied level determination signals, and applies the phase control signal to the phase shifters PS1 to PS8 according to the stored level determination signals. Similar to the voltage determination module 21, the voltage fixing module 22 also outputs the applied second power supply voltage VDD2 to be transmitted to the control apparatus 13 of the RIS unit, which is disposed adjacent thereto through the second pads.

Here, the first power supply voltage VDD1 and the second power supply voltage VDD2 are independently driven. This is to enable the voltage determination module 21 to output a first voltage level determination signal, then block the power of the first power supply voltage VDD1 and apply only the second power supply voltage to drive only the voltage fixing module 22. As described above, the control apparatus 13 may be implemented as the chip 14, and generally, a circuit inside a chip is driven by one power supply voltage. However, the voltage determination module 21 is driven by the two power supply voltages VDD1 and VDD2 in order to implement a control apparatus that can reduce power consumption by blocking power after the first execution.

In one embodiment, the control apparatus 13 provided in each of the plurality of RIS units 10 has eight second pads for inputting or outputting each of the first and second power supply voltages VDD1 and VDD2, the clock signal CLK, and the serial data SD so that the applied first and second power supply voltages VDD1 and VDD2, the clock signal, and the serial data may be transmitted to the RIS unit 10 disposed adjacent thereto. The first and second power supply voltages VDD1 and VDD2 and the clock signal CLK may be commonly used by the plurality of RIS units 10, and each RIS unit 10 may detect data about itself separately even when the serial data SD passes through the plurality of RIS units 10. Therefore, the RIS of one embodiment may be changed in size or shape in various ways only by adjusting the number of RIS units 10 arranged without the need to modify the design of the RIS unit 10. That is, the RIS of one embodiment may have versatility and expandability.

Further, the second power supply voltage VDD2 may be constantly applied to the voltage fixing module 22, whereas the first power supply voltage VDD1 may be applied to the voltage determination module 21 only during a section in which the serial data SD is applied and the level determination signal is output. That is, the voltage determination module 21 may be activated and driven by the applied first power supply voltage VDD1 only during a section in which the level determination signal is determined according to the serial data SD, and may be deactivated during other sections, and thus power consumption may be reduced. This is because, as described above, the voltage fixing module 22, which is always activated by receiving the second power supply voltage VDD2, may latch and store the level determination signal applied from the voltage determination module 21.

The switch circuit SW is disposed between the voltage determination module 21 and the voltage fixing module 22, transmits the stored level determination signal of the voltage fixing module 22 in the reverse direction to the voltage determination module 21 when the first power supply voltage VDD1 applied to the voltage determination module 21 is blocked, and thus prevents the level of the stored level determination signal from being changed. That is, the switch circuit SW is provided to ensure that the level of the level determination signal stored in the voltage fixing module 22 is stably maintained when the voltage determination module 21 is deactivated. In (b) of FIG. 4, only one switch is illustrated for convenience of description, but the switch circuit SW includes a plurality of switches.

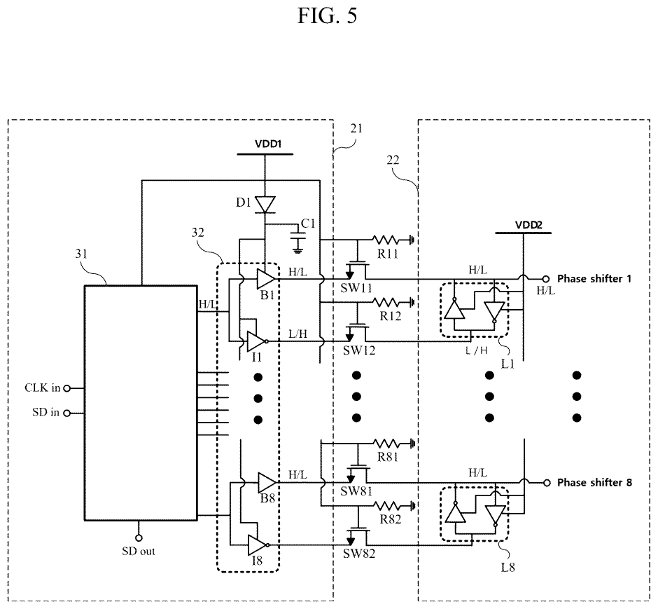

FIG. 5 illustrates an example of a detailed configuration of the control apparatus of FIG. 4.

Referring to FIG. 5, the voltage determination module 21 may include a data interpretation module 31 and a determination signal transmission module 32. The data interpretation module 31 receives a clock signal CLK and serial data SD that are transmitted from an external device or an RIS unit 10 disposed adjacent thereto, and analyzes the applied serial data SD in synchronization with the applied clock signal CLK. In addition, the data interpretation module 31 extracts data about itself from the applied serial data SD, obtains a plurality of level determination signals for controlling a plurality of phase shifters PS1 to PS8 according to the extracted data, and outputs the plurality of level determination signals to the determination signal transmission module 32.

The determination signal transmission module 32 buffers the plurality of level determination signals applied from the data interpretation module 31 and transmits the plurality of level determination signals to the voltage fixing module 22. The determination signal transmission module 32 may include a plurality of buffer modules each which buffers the level determination signal. In addition, the plurality of buffer modules may each include inverters I1 to I8 together with buffers B1 to B8 to convert each of the applied level determination signals into a differential signal and transmit the converted differential signal. In order to improve the driving ability of the level determination signal transmitted to the determination signal transmission module 32, the buffer module includes not only the buffers B1 to B8 but also the inverters I1 to I8 in order to convert the level determination signal into the differential signal. As described above, the voltage determination module 21 is driven by the first power supply voltage VDD1, and thus the level determination signal has the first power supply voltage VDD1 and ground voltage GND levels at high and low levels. However, since the voltage fixing module 22 is driven by the first power supply voltage VDD1 and the second power supply voltage VDD2 that are independent, when the level determination signal has the first power supply voltage VDD1 level at a high level, the level determination signal may not be stably transmitted to the voltage fixing module 22. In consideration of the above, the plurality of buffer modules are provided with not only the buffers B1 to B8 but also the inverters I1 to I8 to convert the level determination signal into the differential signal, thereby allowing the level determination signal to be stably applied to the voltage fixing module 22.

Meanwhile, the voltage determination module 21 may further include a capacitor C1 connected in parallel between the first power supply voltage VDD1 and the determination signal transmission module 32. The capacitor C1 serves to allow the plurality of buffer modules of the determination signal transmission module 32 to maintain operation for a certain period of time even when the first power supply voltage VDD1 is blocked. This is to prevent the level determination signal latched to the voltage fixing module 22 from being changed by ensuring that the plurality of buffer modules are deactivated after the switch circuit SW is turned off. Further, the voltage determination module 21 may further include a diode D1 connected to in series between the first power supply voltage VDD1 and the determination signal transmission module 32 to prevent electric charges charged in the capacitor C1 from flowing through the first power supply voltage VDD1.

The switch circuit SW includes a plurality of switches (SW11 and SW12) to (SW81 and SW82) that connect the voltage determination module 21 and the voltage fixing module 22 while the first power supply voltage VDD1 is applied, to transmit a differential level determination signal converted into a differential signal, and when the first power supply voltage VDD1 is blocked, disconnect the voltage determination module 21 and the voltage fixing module 22 to block the transmission of the differential level determination signal. Since the level determination signal is converted into the differential signal in a determination signal transmission module 32, the switch circuit SW may include two switches (SW11 and SW12) to (SW81 and SW82) for each differential level determination signal. Each of the switches (SW11 and SW12) to (SW81 and SW82) may be implemented as a transistor in which the first power supply voltage VDD1 is applied to a gate. The switch circuit SW may further include a plurality of resistors (R11 and R12) to (R81 and R82) connected in parallel to the first power supply voltage VDD1 and the gate in order to prevent damage due to the first power supply voltage VDD1 being directly applied to each of the switches (SW11 and SW12) to (SW81 and SW82). However, the plurality of resistors (R11 and R12) to (R81 and R82) may be omitted.

Meanwhile, the voltage fixing module 22 may include a plurality of latches L1 to L8 that are driven when the second power supply voltage VDD2 is applied. The plurality of latches L1 to L8, each including two inverters, receive differential level determination signals. In this case, each of the latches L1 to L8 level-shifts and stores the differential level determination signal applied with the first power supply voltage VDD1 and ground voltage GND levels into a differential phase control signal with the second power supply voltage VDD2 and ground voltage GND levels, and outputs the phase control signal from among the stored differential phase control signal to the phase shifters PS1 to PS8. That is, the voltage fixing module 22 may not only receive the differential level determination signal and store the received differential level determination signal as the differential phase control signal, but also may serve as a level shifter that converts the level determination signal of the first power supply voltage VDD1 level into the phase control signal of the second power supply voltage VDD2 level.

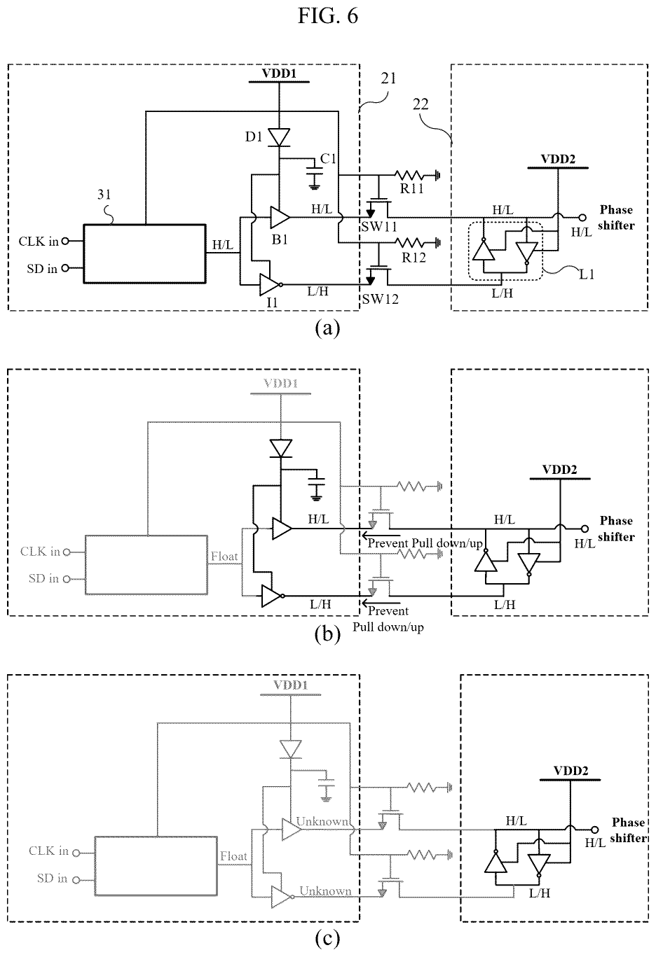

FIG. 6 is a set of diagrams for describing operations of the control apparatus of FIG. 4.

In FIG. 6, (a) of FIG. 6 illustrates a state in which both the first and second power supply voltages VDD1 and VDD2 are applied to the control apparatus 13 and both the voltage determination module 21 and the voltage fixing module 22 are activated, (b) of FIG. 6 illustrates an operation when the first power supply voltage VDD1 is blocked, and (c) of FIG. 6 illustrates an operation in a state in which only the voltage fixing module 22 is activated after the first power supply voltage VDD1 is blocked.

As illustrated in (a) of FIG. 6, in the state in which both the first and second power supply voltages VDD1 and VDD2 are applied and both voltage determination module 21 and the voltage fixing module 22 are activated, the voltage determination module 21 obtains a plurality of level determination signals for controlling the plurality of phase shifters PS1 to PS8 on the basis of applied serial data, and output the plurality of obtained level determination signals to the voltage fixing module 22. In this case, since the plurality of switches (SW11 and SW12) to (SW81 and SW82) of the switch circuit SW are in a state of being turned on by the first power supply voltage VDD1, the plurality of level determination signals are transmitted to the voltage fixing module 22. Accordingly the voltage fixing module 22 receives the plurality of level determination signals, level shifts the plurality of level determination signals to store the phase control signal, and outputs the stored phase control signal to the plurality of phase shifters PS1 to PS8.

Thereafter, as illustrated in (b) of FIG. 6, when the first power supply voltage VDD1 is blocked, the data interpretation module 31 of the voltage determination module 21 is deactivated, and the plurality of switches (SW11 and SW12) to (SW81 and SW82) of the switch circuit SW are turned off to cut off the connection between the voltage determination module 21 and the voltage fixing module 22. However, the determination signal transmission module 32 of the voltage determination module 21 is deactivated more slowly than the switches (SW11 and SW12) to (SW81 and SW82) by the capacitor C1, and thus allows the phase control signal stored in the voltage fixing module 22 not to be changed when the first power supply voltage VDD1 is blocked.

Meanwhile, when all electric charges charged in the capacitor C1 are discharged so that the determination signal transmission module 32 is also deactivated, only the voltage fixing module 22 that receives the second power supply voltage VDD2 remains the activated state and outputs the stored phase control signal to the plurality of phase shifters PS1 to PS8.

As a result, the RIS unit 10 according to one embodiment has high versatility and expandability, as it can be changed in size and shape of the RIS by simply adjusting the number of RIS units 10 arranged without the need to modify the design while including the plurality of radiators 12. Further, after the level determination signal is obtained, although the first power supply voltage VDD1 may be blocked and the voltage determination module 21 may be deactivated, there is no problem, thereby reducing power consumption.

Thereafter, in the case in which it is desired to adjust the phase of the signal of the RIS unit 10, the first power supply voltage VDD1 may be applied again to enable receiving the clock signal CLK and the serial data.

In the illustrated embodiment, each component may have different functions and capabilities in addition to those described below, and may include additional components other than those described below. Further, in an embodiment, each component may be implemented using one or more physically separate devices, one or more processors, or a combination of one or more processors and software, and, unlike the shown examples, the component may not be clearly distinguished in terms of its specific operation.

In addition, the RIS and the control apparatus for the RIS, as illustrated in FIG. 1, may be implemented in a logic circuit using hardware, firmware, software, or a combination thereof, and may also be implemented using a general-purpose or special-purpose computer. The RIS and the control apparatus for the RIS may be implemented using hardwired devices, field programmable gate arrays (FPGAs), application specific integrated circuits (ASICs), etc. Further, the RIS and the control apparatus for the RIS may be implemented as a system on chip (SoC) including one or more processors and a controller.

In addition, the RIS and the control apparatus for the RIS may be mounted on a computing device or server equipped with hardware elements in the form of software, hardware, or a combination thereof. The computing device or the server may be various devices that include all or part of communication devices such as communication modems for communicating with various devices or wired and wireless communication networks, memories for storing data for executing programs, microprocessors for executing programs to perform calculations and commands, etc.

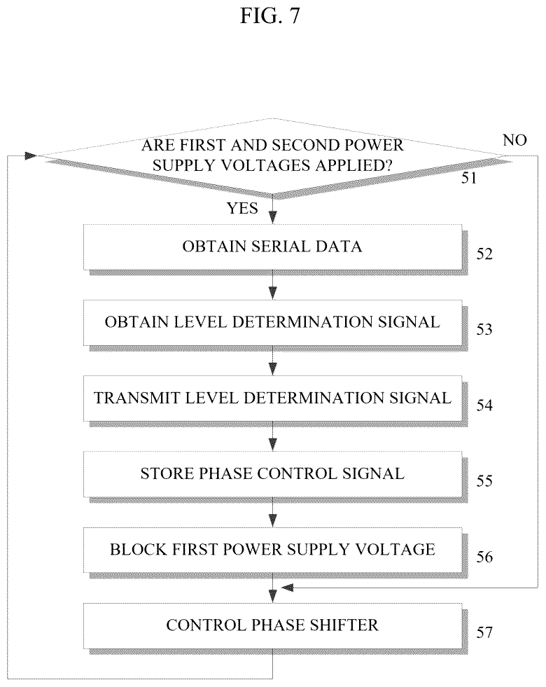

FIG. 7 illustrates a control method for an RIS according to one embodiment.

First, each of a plurality of RIS units 10 constituting the RIS checks whether first and second power supply voltages VDD1 and VDD2 are applied (51). When both the first and second power supply voltages VDD1 and VDD2 are applied, both a voltage determination module 21 and a voltage fixing module 22 of a control apparatus 13 including a plurality of phase shifters PS1 to PS8 that adjust phases of signals applied to a plurality of radiators 12 included in the RIS unit 10 are activated, and a switch circuit SW that connects the voltage determination module 21 and the voltage fixing module 22 is also activated.

The activated voltage determination module 21 receives and obtains a clock signal CLK and serial data SD transmitted from an external device or an RIS unit adjacent thereto (52). In addition, by analyzing the serial data SD in synchronization with the applied clock signal CLK, a plurality of level determination signals are obtained (53). When the plurality of level determination signals are obtained, the plurality of level determination signals are converted into differential signals having first power supply voltage VDD1 and ground voltage GND levels, and the differential level determination signals are transmitted to the voltage fixing module 22 through the switch circuit SW (54).

When the differential level determination signal is applied through the switch circuit SW, the voltage fixing module 22 level-shifts the differential level determination signal to a differential phase control signal having the second power supply voltage VDD2 and ground voltage GND levels and stores the differential phase control signal (55). When the differential phase control signal is stored in the voltage fixing module 22, the first power supply voltage VDD1 applied to the voltage determination module 21 and the switch circuit SW is blocked so that power consumption can be reduced (56). In this case, the voltage determination module 21 is deactivated later than the voltage fixing module 22 using a capacitor C1 provided therein so that the differential phase control signal stored in the voltage fixing module 22 may not be changed.

Meanwhile, the voltage fixing module 22 applies the phase control signal among the stored differential phase control signals to the connected phase shifters PS1 to PS8 so that the phase shifters PS1 to PS8 adjust the phases of the signals applied to the radiators 12 electrically connected thereto (57).

In FIG. 7, the respective processes are described as being sequentially executed, but this is only an illustrative explanation, and those skilled in the art can change the order illustrated in FIG. 7 and execute the processes without departing from the essential characteristics of the embodiments of the present disclosure, or the processes may be applied through various modifications and alternative forms by executing one or more processes in parallel or adding other processes.

The RIS and the control apparatus and method thereof of the present disclosure can include a control module included in each RIS unit and including a plurality of phase shifters for controlling phases of signals applied to a plurality of radiators, respectively, and thus high versatility and expandability can be achieved as well as power consumption can be reduced.

While the present disclosure has been described with reference to embodiments illustrated in the accompanying drawings, these should be considered in a descriptive sense only and it will be understood by those skilled in the art that various alterations and other equivalent embodiments may be made. Therefore, the scope of the present disclosure is defined by the appended claims.

What is claimed is:

1. A control apparatus for a Reconfigurable Intelligent Surface (RIS) unit, comprising:
a voltage determination module that is activated when a first power supply voltage is applied, receives serial data, and obtains a plurality of level determination signals;
a voltage fixing module that is driven when a second power supply voltage is applied, and stores a plurality of phase control signals obtained by level-shifting each of the plurality of level determination signals transmitted from the voltage determination module; and
a phase shifting module configured to adjust a phase of a signal received by each of a plurality of radiators according to the plurality of phase control signals.

2. The control apparatus of claim 1, wherein the first power supply voltage is applied before the serial data is transmitted, and is blocked after the plurality of phase control signals are stored in the voltage fixing module.

3. The control apparatus of claim 1, wherein the voltage determination module includes:
a data interpretation module that extracts the plurality of level determination signals from the serial data in synchronization with a clock signal applied together with the serial data; and
a buffer module that converts each of the plurality of level determination signals into a differential signal and outputs a plurality of differential level determination signals.

4. The control apparatus of claim 3, wherein the buffer module includes:
a buffer that receives the level determination signals, buffers the level determination signals, and outputs the level determination signals; and
an inverter that receives the level determination signals, inverts the level determination signals, and outputs the inverted level determination signals.

5. The control apparatus of claim 3, wherein the voltage determination module further includes:
a diode connected in series between the first power supply voltage and the buffer module; and
a capacitor connected in parallel between the diode and the buffer module.

6. The control apparatus of claim 1, further comprising a switch circuit that is positioned between the voltage determination module and the voltage fixing module and electrically connects the voltage determination module and the voltage fixing module when the first power supply voltage is applied.

7. The control apparatus of claim 1, wherein the voltage fixing module includes a plurality of latches that are driven when the second power supply voltage is applied, and receive and store each of the plurality of level determination signals.

8. The control apparatus of claim 1, wherein the phase shifting module includes a plurality of phase shifters that are implemented as transistors, wherein the transistors are connected between one of the plurality of radiators and a ground voltage and connect or disconnect the radiator and the ground voltage according to a level of a corresponding one of the plurality of phase control signals.

9. A control method for a Reconfigurable Intelligent Surface (RIS) unit, which is a method performed by a control module included in the RIS unit in which a plurality of radiators are arranged, the control method comprising:
when a first power supply voltage is applied, receiving serial data and obtaining a plurality of level determination signals;
storing a plurality of phase control signals obtained by level-shifting each of the plurality of level determination signals into a signal according to a second power supply voltage; and
adjusting a phase of a signal received by each of the plurality of radiators according to the plurality of phase control signals.

10. The control method of claim 9, wherein the first power supply voltage is applied before the serial data is transmitted, and is blocked after the plurality of phase control signals are stored.

11. The control method of claim 9, wherein, in the obtaining of the plurality of level determination signals, the plurality of level determination signals are extracted from the serial data in synchronization with a clock signal applied together with the serial data, and
each of the plurality of level determination signals is converted into a differential signal and a plurality of differential level determination signals are output.

12. The control method of claim 11, wherein, in the obtaining of the plurality of level determination signals, the level determination signals are buffered, and the level determination signals are inverted simultaneously with the buffering to obtain the differential level determination signals.

13. The control method of claim 11, wherein, in the obtaining of the plurality of level determination signals, a capacitor is used so that the differential level determination signals are maintained for a certain period of time even after the first power supply voltage is blocked.

14. The control method of claim 9, wherein, when the first power supply voltage is applied, the phase control signals are changed according to the level determination signals, and when the first power supply voltage is blocked, the stored phase control signals are maintained.

15. A Reconfigurable Intelligent Surface (RIS) comprising:
a plurality of radiators; and
a plurality of RIS units that each include a control module that receives serial data and obtains a plurality of level determination signals when a first power supply voltage is applied, stores a plurality of phase control signals obtained by level-shifting each of the plurality of level determination signals into a signal according to a second power supply voltage, and adjusts a phase of a signal received by each of the plurality of radiators according to the plurality of phase control signals.

16. The RIS of claim 15, wherein the control module includes:
a voltage determination module that is activated when the first power supply voltage is applied, and receives the serial data, and obtains the plurality of level determination signals;
a voltage fixing module that is driven when the second power supply voltage is applied, stores the plurality of phase control signals obtained by level-shifting the plurality of level determination signals transmitted from the voltage determination module; and
a phase shifting module controlled according to the plurality of phase control signals.

17. The RIS of claim 15, wherein the first power supply voltage is applied before the serial data is transmitted, and is blocked after the plurality of phase control signals are stored.

18. The RIS of claim 16, wherein the voltage determination module includes:
a data interpretation module that extracts the plurality of level determination signals from the serial data in synchronization with a clock signal applied together with the serial data; and
a buffer module that converts each of the plurality of level determination signals into a differential signal and outputs a plurality of differential level determination signals.

19. The RIS of claim 18, wherein the voltage determination module further includes:
a diode connected in series between the first power supply voltage and the buffer module; and
a capacitor connected in parallel between the diode and the buffer module.

20. The RIS of claim 16, wherein the control module further includes a switch circuit that is positioned between the voltage determination module and the voltage fixing module and electrically connects the voltage determination module and the voltage fixing module when the first power supply voltage is applied.
